(19) United States
(12) Patent Application Publication
(10) Pub. No.: US 2014/0339568 A1
(43) Pub. Date: Nov. 20, 2014

(54) SEMICONDUCTOR DEVICE WITH SUBSTRATE VIA HOLE AND METHOD TO FORM THE SAME

(71) Applicant: SUMITOMO ELECTRIC INDUSTRIES, LTD., Osaka-shi (JP)

(72) Inventor: Ken KIKUCHI, Kofu-shi (JP)

(73) Assignee: SUMITOMO ELECTRIC INDUSTRIES, LTD., Osaka-shi (JP)

(21) Appl. No.: 13/895,509

(22) Filed: May 16, 2013

(51) Int. Cl. H01L 23/48; H01L 27/088; H01L 29/16; H01L 29/20; H01L 29/66; H01L 29/78

(52) U.S. Cl. CPC H01L 23/481; H01L 29/66477; H01L 29/78; H01L 29/1608; H01L 29/2003; H01L 27/088
USPC 257/77; 438/197; 257/288; 257/76; 257/368

(57) ABSTRACT

A process to form a substrate via hole is disclosed. The process includes steps of (1) forming a semiconductor layer on a substrate; (2) forming a gate and an auxiliary electrode simultaneously on a semiconductor layer; and (3) etching the substrate and the semiconductor layer from the back surface of the substrate to the auxiliary electrode to form a substrate via hole. A feature of the process is that the gate and the auxiliary electrode include a nickel or a metal primarily containing nickel in contact with the semiconductor layer. The nickel operates as an etching stopper for drilling the substrate and the semiconductor layer.

### BACKGROUND OF THE INVENTION

1. Field of the Invention

The present application relates to a method to form a semiconductor device, in particular, a method including a process to form a substrate via holes.

2. Related Background Arts

Substrate via holes to reduce source inductance and to enhance heat dissipation has been well known technique for a field effect transistor (hereafter denoted as FET) operable in high frequencies and in high power. The substrate via hole pierces from the back surface of the substrate to electrodes of an FET provided in the front surface. However, when the substrate via hole reaches the electrode, the etching carried out to form the via hole possibly etches a portion of the electrode.

### SUMMARY OF THE INVENTION

One aspect of the present application relates to a method to form a semiconductor device, in particular, the application relates to a method to form a substrate via hole. The process includes steps of: (1) forming a semiconductor layer on a substrate; (2) forming a gate and an auxiliary electrode simultaneously on a semiconductor layer, the gate and the auxiliary electrode including a nickel or a metal primarily containing nickel in a side in contact with the semiconductor layer; and (3) etching the substrate and the semiconductor layer from a back surface of the substrate to the auxiliary electrode to form a substrate via hole.

A feature of the process is that, the semiconductor layer includes nitride semiconductor materials, and the substrate is one of silicon carbide (SiC), sapphire (Al₂O₃), and gallium nitride (GaN), where they are popular selection for the nitride semiconductor device. Further feature of the process is that the auxiliary electrode to which the substrate via hole is to be drilled includes nickel or another metal primarily containing nickel; and this auxiliary electrode is formed simultaneously with the gate. Nickel shows a quite small etching rate compared with materials for the substrate and the semiconductor layers; accordingly, the etching or drilling for the substrate via hole may be securely stopped at the nickel or the metal primarily containing nickel.

Another aspect of the present application relates to a field effect transistor (FET). The FET includes a substrate; a nitride semiconductor layer; a gate including; an auxiliary electrode; and a substrate via hole. The substrate has a primary surface and a back surface. The nitride semiconductor layer is provided on the primary surface of the substrate. Each of the gate and the auxiliary electrode includes a metal primarily including nickel (Ni). The substrate via hole pierces from the back surface of the substrate to the metal primarily including Ni of the auxiliary electrode. Because the gate and the auxiliary electrode have an arrangement same to each other, the auxiliary electrode may reduce inductance of the electrode of the FET without degrading the performance thereof.

### BRIEF DESCRIPTION OF THE DRAWINGS

The foregoing and other purposes, aspects and advantages will be better understood from the following detailed description of a preferred embodiment of the invention with reference to the drawings, in which:

FIGS. 1A to 1E are cross sections showing a process according to an embodiment of the invention to form a semiconductor device;

FIGS. 2A to 2E are cross sections of the process subsequent to that shown in FIG. 1E;

FIGS. 3A to 3C are cross sections of the process subsequent to that shown in FIG. 2E;

FIGS. 4A and 4B are cross sections of the process subsequent to that shown in FIG. 3C;

FIGS. 5A and 5B are cross sections of the process subsequent to that shown in FIG. 4B;

FIGS. 6A and 6B are cross sections of the process subsequent to that shown in FIG. 5B;

FIG. 7 is a plan view of the semiconductor device formed by the process shown in FIGS. 1 to 6;

FIGS. 8A to 8C are plan views of modified auxiliary electrodes formed in the semiconductor device; and

FIGS. 9A and 9B are cross sections of a modified process subsequent to that shown in FIG. 2E.

### DESCRIPTION OF PREFERRED EMBODIMENTS

Next, some preferred embodiments according to the present invention will be described as referring to accompany drawings.

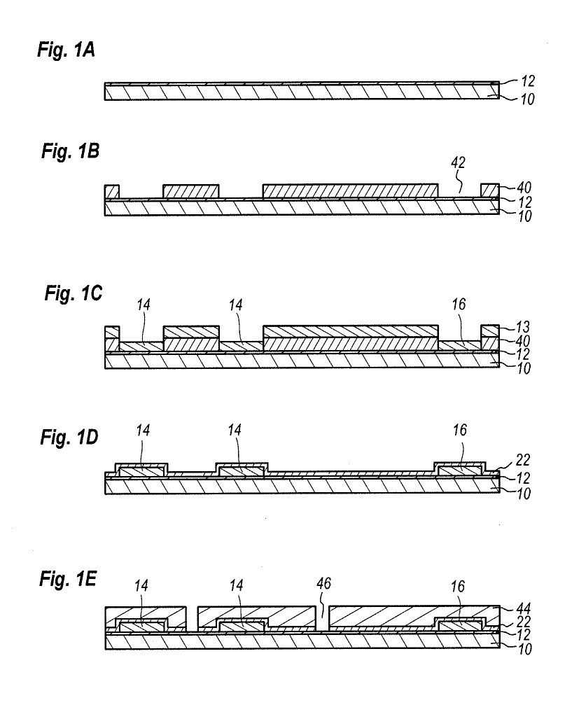

FIGS. from 1A to 6B are cross sections of a semiconductor device during a manufacturing process thereof according to an embodiment of the present invention. A substrate 10 first grows a stack 12 on atop surface thereof as shown in FIG. 1A. The substrate 10 is made of, for instance, silicon carbide (SiC); but the substrate 10 may be made of sapphire (Al₂O₃), gallium nitride (GaN), and so on, where they are often provided for nitride semiconductor devices. The stack 10 includes semiconductor layers types of a group III-V nitride semiconductor; specifically, the stack 10 includes, from the substrate 10, a buffer layer made of AlN, a channel layer made of GaN, a doped layer made of AlGaN, and a cap layer made of GaN. These layers in the stack 12 are grown by, for instance, the metal organic chemical vapor deposition (MOCVD) technique.

FIG. 1B forms a photoresist pattern 40 with an opening 42 on the stack 12; while, FIG. 1C fills the opening 42 with an ohmic metal 13. The ohmic metal 13 is also deposited on the photoresist 40. The ohmic metal 13 may be made of stacked metals of tantalum (Ta) and aluminum (Al) from the side of the stack 12 and formed by, for instance, the metal evaporation. The Ta has a thickness of 30 nm, while, the Al has a thickness of 300 nm. The process forms also electrodes of the source 14 and the drain 16 in respective openings 42 on the stack 12, as shown in FIG. 1C.

FIG. 1D removes the ohmic metal 13 deposited on the photoresist 40 by, what is called, the lift-off technique; then forms an insulating film 22 to cover the source 14 and the drain electrodes 16. The insulating film 22 is made of silicon nitride (SiN) formed by the chemical vapor deposition (CVD) technique. FIG. 1E forms another photoresist 44 with an opening 46 on the insulating film 22; then, a portion of the insulating film 22 exposed within the opening 46 of the photoresist 44 is selectively is etched. The etching of the insulating film 22 exposes the top of the stack 12 between the source electrode 14 and the drain electrode 16 at the opening 46. The photoresist 44 in the edges of the opening 46 preferably has a cross section of a reverse tapered shape.

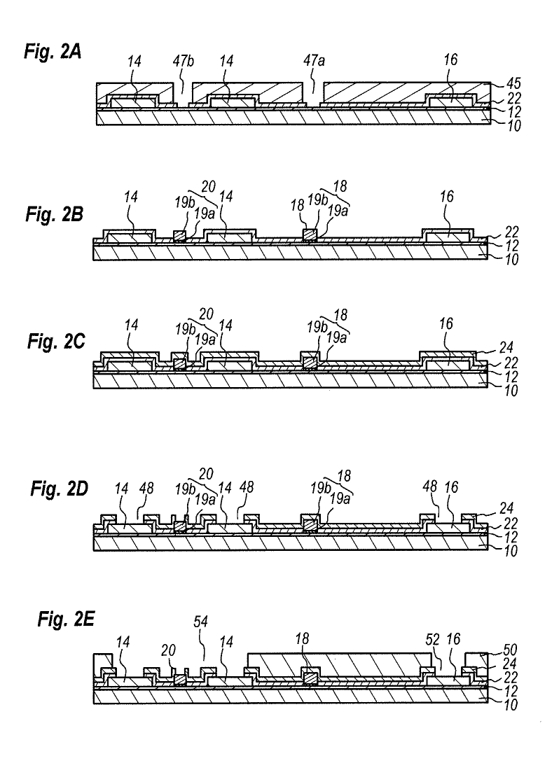

FIG. 2A forms still another photoresist 45 with openings, 47a and 47b, on the top of the stack 12 after removing the aforementioned photoresist 44. This photoresist 45 is used as a mask for forming a metal for the gate electrode. Specifically, the opening 47a is formed at a position between the source 14 and the drain 16 where the gate electrode is to be formed. The other opening 47b is formed apart from the former opening 47a. These openings, 47a and 47b, have a dimension wider than a width of the aforementioned opening 46 in the insulating film 22 and expose the whole of the former opening 46.

FIG. 2B lifts the gate metal off; specifically, a first metal of nickel (Ni) 19a with a thickness of 50 nm and a second metal of gold (Au) with a thickness of 400 nm are sequentially deposited within the openings, 47a and 47b, and on the photoresist 45 by the metal evaporation; then, the stacked metal of Ni and Au on the photoresist 45 is removed by the lift-off technique as removing the photoresist 45 to leave the stacked metal of Ni and Au within the openings, 47a and 47b, as the gate electrode 18 and the auxiliary electrode 20. The source 14 and the drain 16 put the gate 18 therebetween, while, the auxiliary electrode 20 is put between the electrodes 14. FIG. 2C forms another insulating film 24 so as to cover the gate 18, the auxiliary electrode 20 and the the first insulating film 22. The latter insulating film 24 is also made of SiN formed by the CVD technique.

FIG. 2D forms openings 48 at positions on the electrodes, 14 to 20 of the second insulating film 24 to expose tops of respective electrodes, 14 to 20, except for the gate 18. FIG. 2E forms a photoresist 50 with openings, 52 and 54. The former opening 52 exposes the top of the drain 16 and the top of the second insulating film 24; while, the latter opening 54 exposes the top of the source electrode 14, that of the auxiliary electrode 20, and that of the second insulating film 24 between the electrodes 14.

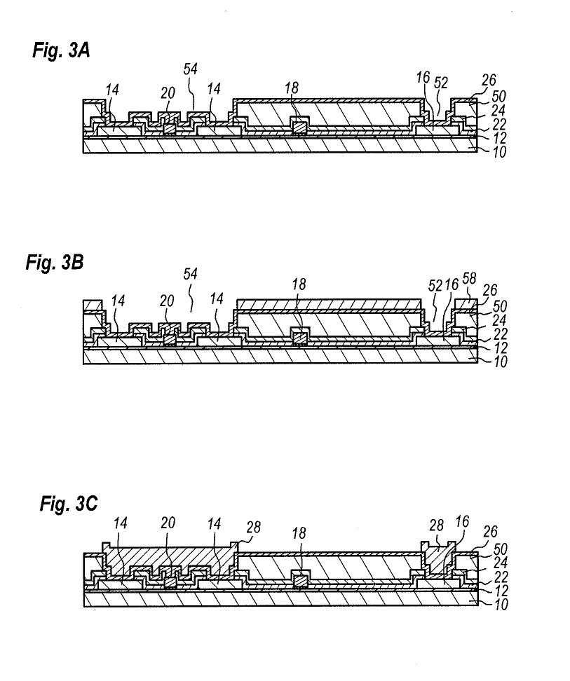

FIG. 3A forms a seed metal 26 on the photoresist 54 and within the openings, 52 and 54, by sputtering. The seed metal 26 is made of titanium (Ti) and gold (Au) from the side of the substrate 10. Because the seed metal 26 is deposited by sputtering, the side walls of the photoresist 50, and that of the insulating films, 22 and 24, in respective openings, 52 and 54, are covered by the sputtered seed metal 54. FIG. 3B forms a photoresist 58 so as to expose a whole of the openings, 52 and 54. FIG. 3C selectively forms another metal 28 made of gold (Au) on the seed metal 26 by electrolytic plating. The seed metal 26 provides the current path for the plating. Removing the photoresist 58, the plated metal 28 is left to fill the opening 52 on the drain electrode 16 and the opening 54 on two source electrodes 14 and the auxiliary electrode 20.

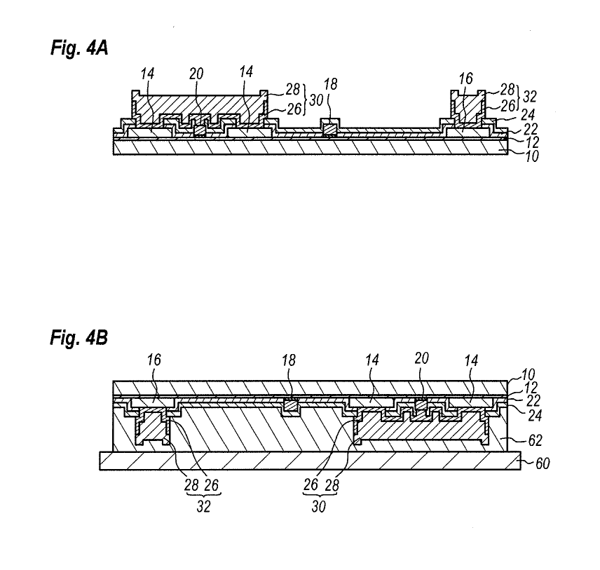

FIG. 4A sequentially removes the seed metal 26 exposed between the plated metals 28 and the photoresist 50 covered by the seed metal 26. Thus, the seed metal 26 with the plated metal 28 thereon, which is referred as an interconnection 30, electrically connects the source electrode 14 and the auxiliary electrode 20, and another interconnection 32 also containing the seed metal 26 and the plated metal 28 is left on the drain electrode 16. FIG. 4B attaches the semiconductor substrate 10 to a support 60 such that the stack 12 and interconnections, 30 and 32, face the support 60 as putting a protecting film 62 therebetween. The protecting film 62 is made of, for instance, resin such as wax, chemical film and so on; while, the support 60 is made of glass. Then, the substrate 10 in an exposed surface thereof may be thinned by polishing.

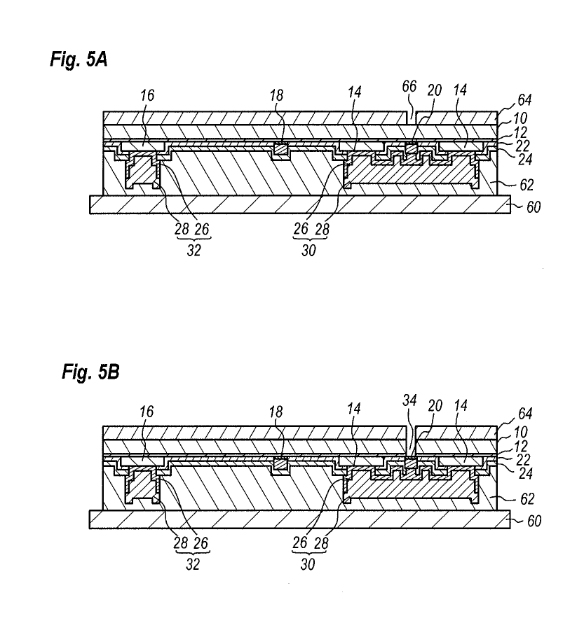

FIG. 5A forms a mask 64 with an opening 66. The mask 64 includes nickel (Ni), which means that the mask is made of Ni only, and/or made of metal containing at least Ni in a primary portion thereof. Then, the substrate 10 and the stack 12 are sequentially etched by the mask 64 as an etching mask. The reactive ion etching (RIE) and/or the inductively coupled plasma etching (ICP) are used by a reactive gas containing fluorine (F) or chlorine (Cl). For instance, when the substrate 10 is made of semiconductor material, the reactive gas containing sulfur fluoride (SF₆), fluorocarbon (CF₄), nitrogen fluoride (NF₃), and so on may etch the substrate. While, the stack 12 is carried out by the reactive gas containing chlorine (Cl₂), boron chloride (BCl₃), silicon chloride (SiCl₄), and so on. The etching forms a via hole 34, which is called as the substrate via hole, as shown in FIG. 5C, reaching the auxiliary electrode 20 from the back surface of the substrate 10. Because nickel (Ni) is hard to be etched by the reactive gas primarily containing chloride (Cl), Ni 19a in the auxiliary electrode 20 operates as an etching stopper. Thus, the substrate via hole 34 is easily formed from the back surface of the substrate 10 to the auxiliary electrode 20 piercing through the stack 12.

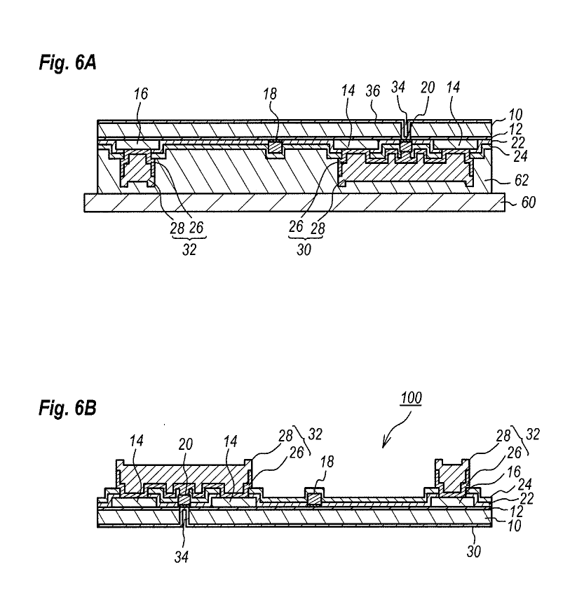

FIG. 6A removes the mask 64 and covers the substrate via hole 34 and the back surface of the substrate 10 with a back metal 36 made of Au by, for instance, plating. FIG. 6B detaches the support 60 by resolving the protecting film 62. Thus, a semiconductor device 100 is completed.

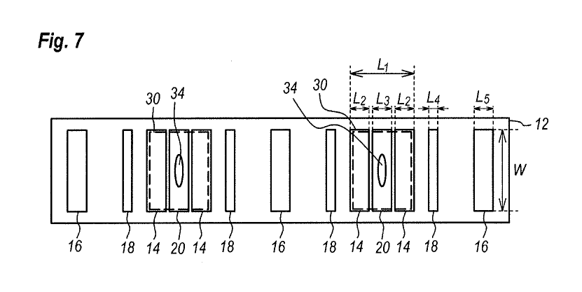

FIG. 7 is a plan view of a semiconductor device with a plurality of fingers. FIG. 7 omits a finger bar connecting fingers and some pads to which a bonding wire is attached but explicitly shows substrate via holes formed in the auxiliary electrodes. As shown in FIG. 7 the drains 16, the gates 18, the sources 14, and the auxiliary electrodes 20 are formed on the stack 12. One substrate via hole is provided in the auxiliary electrode 20. The gates 18 are formed in a side opposite to the auxiliary electrode 20 with respect to the sources 14, and the drains are formed in a side opposite to the source 14 with respect to the gate 18. That is, two set of the gate, source, and drain are formed so as to put the auxiliary electrode 20 therebetween. Respective fingers have a width W of 300 μm; while, the source has a length L₂ of 5 μm, that of the auxiliary electrode 20 L₃ is, for instance, 80 μm, and a length L₁ of the interconnection connecting the source 14 to the auxiliary electrode 20 is, for instance, 100 μm.

According to the first embodiment, two processes, one of which forms the auxiliary electrode 20 containing Ni film 19a on the stack 12, while, the other of which forms the electrode 18 also containing Ni film 19a on the stack 12, are concurrently or simultaneously carried out. The auxiliary electrode 20, which operates as a stopping layer for etching the substrate 10 and the stack 12 to form the substrate via hole 34 and electrically connected to the source 14, is formed concurrently with the formation of the gate 18. Thus, the auxiliary electrode 20, the thickness and the materials thereof, is same with those of the gate 18.

The first embodiment described above provides Ni layer 19a as the first metal. Conditions requested for the first metal 19a is only that the first metal is constituted by a single layer containing Ni. For instance, the first metal 19a is made of substantially Ni only, or other metal primarily containing Ni. Such a metal has a function to stop etching for forming the substrate via hole 34. Also, the first metal 19a operates as a Schottky metal for the stack 12.

The auxiliary electrode 20, which includes Ni 19a and Au 19b, is simultaneously formed with the formation of the gate 18. Moreover, the auxiliary electrode 20, or the gate 18 has the multi-metal structure of Ni 19a and Au 19b; accordingly, a total height or thickness of the auxiliary electrode 20 becomes substantially equal to the source 14, or the drain 16. Then, the second insulating film 24 forms substantially no steps, and the plated metal 28 formed on the second insulating film 24 is also formed in planar. When the gate 18 and the auxiliary electrode 20 provides only Ni 19a, which causes no influence for the device performance, inevitably brings steps in the second insulating film 24 and the plated metal 28. Accordingly, a sequential deposition of Ni 19a and Au 19b for the formation of gate 18 and the auxiliary electrode 20 is preferable. Any metal may be substituted for Au in the second metal 19b. However, the second metal 19b has a function to reduce gate resistance; the second metal 19b preferably has resistance lower than that of the first metal of Ni.

As shown in FIG. 4A, the interconnection 30 is formed in both sides of the auxiliary electrode 20, namely, between the auxiliary electrode 20 and two sources 14, and electrically connected to the source 14 and the auxiliary electrode 20. Also, the back metal 36 covers the side of the substrate via hole 34 and comes in contact with the auxiliary electrode 20. Accordingly, the source 14 is electrically connected to the back metal 36, which effectively reduces the source inductance.

As shown in FIG. 2D, the source 14 is offset from the auxiliary electrode 20, specifically, the source 14 does not overlap with the auxiliary electrode 20. Then, the top level of the source 14 and that of the auxiliary electrode 20 is aligned, which effectively prevents the photoresist 50 from being left within the opening 54, which stabilizes the processes after that shown in FIG. 2D, and makes the top of the plated metal 30 shown in FIG. 4A in planar.

Also, as shown in FIG. 2D, the source 14 is apart from the auxiliary electrode 20. In such a case, no metals are preferably formed between the source 14 and the auxiliary electrode 20, which makes a distance between the source 14 and the auxiliary electrode 20 shorter. Moreover, insulating films, 22 and 24, are preferably formed between the source 14 and the auxiliary electrode 20, which makes the top of the plated metal 30 in further planar. Moreover, as described before, the top of the source 14 and that of the auxiliary electrode 20 is preferably aligned.

As shown in FIG. 7, one unit including the source 14, the gate 20, and the drain 18 is formed in both sides of the auxiliary electrode 20 by an arrangement where the source 14 is closest to the auxiliary electrode 20, which facilitates to ground the source 14, because the auxiliary electrode 20 put between the sources 14 is directly and electrically connected to the back metal 36. Moreover, the sources 14 putting the auxiliary electrode 20 therebetween are electrically connected by the interconnection 30, which effectively grounds the source 14 without increasing impedance and shrinks an area of a multi-finger FET.

As shown in FIG. 5B, the process forms the substrate via hole 34 by etching the substrate 10 and the stack 12 from the back surface of the substrate 10. In this etching process, Ni 19a contained in the auxiliary electrode 20 shows the function of the etching stopper.

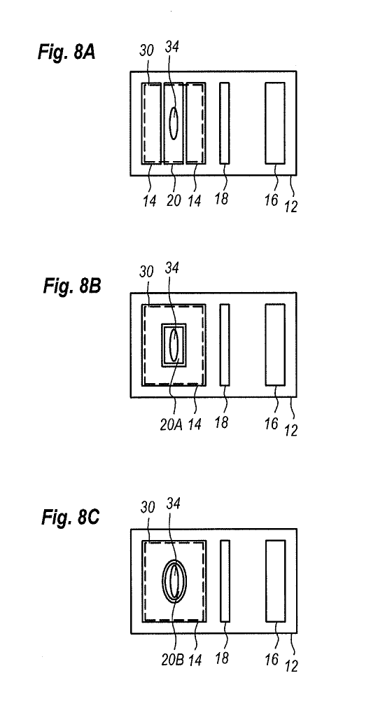

FIGS. 8A to 8C are plan views showing modified arrangement of the auxiliary electrode 20 and the source 14. The sources 14 are basically arranged in both sides of the auxiliary electrode 20 as described above and shown in FIG. 8A. However, the source 14 may surround the auxiliary electrode 20 as shown in FIG. 8B, or, the auxiliary electrode 20 may have an ellipsoidal plane shape. The source 14 is formed in at least one sides of the auxiliary electrode 20. Arranging the sources 14 in both sides of the auxiliary electrode 20, a multi-fingered FET is easily formed.

Although embodiments above described provides the auxiliary electrode 20 independent of the source 14, an source pad to which the wire-bonding is to be carried out substitutes the auxiliary electrode 20, or a drain pad or a gate may substitute the auxiliary electrode 20.

As shown in FIGS. 8A to 8C, the auxiliary electrode 20 may fully cover the substrate via hole 34 to prevent the insulating films, 22 and 24, around the auxiliary electrode 20 from being etched.

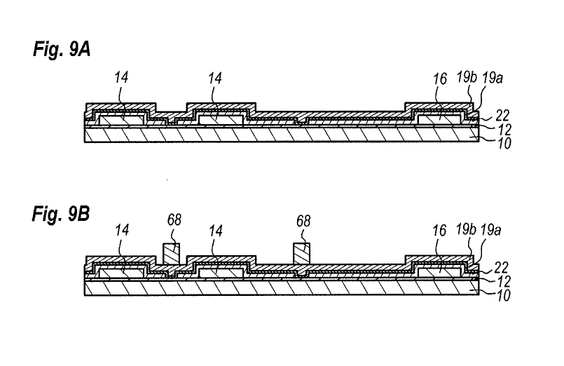

FIGS. 9A and 9B are cross sections showing a modified process of the embodiment. Referring to FIG. 9A, the photoresist 44 shown in FIG. 1E is removed, and a double metal layer made of Ni 19a as the first metal and Au 19b as the second metal covers the whole of the insulating film 22 and the stack 12 within the opening 46. The metal evaporation and/or metal sputtering may form this double metal layer 19. Then, a patterned photoresist 68 is formed on the metal layer. The patterned photoresist 68 corresponding to the gate and the auxiliary electrode is formed. The metals, 19a and 19b, in portions not covered by the photoresist 68 are etched by the patterned photoresist 68 as an etching mask. Nitric acid may etch Ni 19a. Thus, the gate electrode 18 and the auxiliary electrode 20 shown in FIG. 2B are simultaneously formed. Processes subsequent to that shown in FIG. 9B are same as those of the first embodiment. The etching of metals, 19a and 19b, also forms the gate electrode 18 and the auxiliary electrode 20 simultaneously without using, what is called, the lift-off process.

In the embodiments thus described, the substrate 10 is preferably silicon carbide (SiC), sapphire (Al₂O₃), gallium nitride (GaN), and so on. Although these materials or the substrates are popular for a GaN based device; the materials inherently show a tolerance for any etching techniques including the dry-etching and the wet-etching. That is, these materials inherently have a quite small etching rate compared to that of other semiconductor materials and/or metals often used for electrodes except for Ni. By selecting Ni as the first metal in contact with the stack, this Ni layer may effectively operate as an etching stopper.

The stack 12 preferably includes nitride semiconductor material such as GaN, AlN, InN, and any compositions thereof. Nickel operates as a Schottky metal for such nitride semiconductor materials, that is, Ni may be used as the gate electrode and the first metal for the auxiliary electrode continuous to the substrate via hole.

In the foregoing detailed description, the method and the apparatus of the present invention have been described with reference to specific exemplary embodiments thereof. It will, however, be evident that various modifications and changes may be made thereto without departing from the broader spirit and scope of the present invention. The present specification and figures are accordingly to be regarded as illustrative rather than restrictive.

What is claimed is:

1. A method to form a semiconductor device, comprising steps of:
forming a semiconductor layer on a substrate;
forming a gate and an auxiliary electrode simultaneously on a semiconductor layer, the gate and the auxiliary electrode including a nickel or a metal primarily containing nickel in a side in contact with the semiconductor layer; and
etching the substrate and the semiconductor layer from a back surface of the substrate to the auxiliary electrode to form a substrate via hole.

2. The method of claim 1,
further including steps of, before forming the gate and the auxiliary electrode,
depositing an insulating film on a whole of the semiconductor layer; and
forming an opening to expose the semiconductor layer,
wherein the gate and the auxiliary electrode fill the opening in the insulating film.

3. The method of claim 1,
wherein the step of forming the gate and the auxiliary electrode includes steps of:
depositing the nickel or the metal primarily containing nickel on the semiconductor layer; and
removing a portion of the nickel or the metal primarily containing nickel except for the gate and the auxiliary electrode.

4. The method of claim 1,
further including a step of forming a source and a drain on the semiconductor layer before etching the substrate,
wherein the source is closer to the auxiliary electrode with respect to drain.

5. The method of claim 4,
further including a step of forming an interconnection between the source and the auxiliary electrode before etching the substrate.

6. The process of claim 1,
wherein the step of forming the gate and the auxiliary electrode includes steps of forming the nickel or the metal primarily containing nickel and another metal made of gold sequentially.

7. The process of claim 1,
further including a step of filling the substrate via hole with a metal.

8. A field effect transistor (FET), comprising:
a substrate having a primary surface and a back surface;
a semiconductor layer including nitride semiconductors, the semiconductor layer being provided on the primary surface of the substrate;
a gate including a nickel or a metal primarily containing nickel as a Schottky metal in contact with the semiconductor layer;
an auxiliary electrode including a nickel or a metal primarily containing nickel in contact with the semiconductor layer; and
a substrate via hole piercing from the back surface of the substrate and reaching the nickel or the metal primarily containing nickel in the auxiliary electrode.

9. The FET of claim 8,
wherein the substrate via hole is filled with metal.

10. The FET of claim 8,
further including a source and a drain, the source being closer to the auxiliary electrode with respect to the drain and electrically connected to the auxiliary electrode.

11. The FET of claim 8,
wherein the gate and the auxiliary electrode further provide a metal stacked on respective nickel or the metal primarily containing nickel.

12. The FET of claim 8,
wherein the substrate is one of silicon carbide (SiC), sapphire (Al₂O₃), and gallium nitride (GaN).

13. A semiconductor apparatus, comprising:
a substrate made of one of silicon carbide (SiC), sapphire (Al₂O₃), and gallium nitride (GaN), the substrate having a primary surface and a back surface;
a semiconductor stack containing a nitride semiconductor material provided on the primary surface of the substrate;
a plurality of active units each including a drain finger, a gate finger and a source finger, the gate finger including nickel or a metal primarily containing nickel in contact with the semiconductor stack;
a plurality of auxiliary electrodes each including nickel or a metal primarily containing nickel; and
a plurality of substrate via holes drilled from the back surface of the substrate to reach the nickel or the metal primarily containing nickel in the auxiliary electrode,
wherein each of the auxiliary electrodes is put between two active units such that the source fingers in respective units are closer to the auxiliary electrode with respect to the drain fingers.

14. The semiconductor apparatus of claim 13,
wherein the auxiliary electrode is electrically connected with source fingers in respective active units putting the auxiliary electrode therebetween.

15. The semiconductor apparatus of claim 13,
wherein the substrate via holes are filled with metal.

16. The semiconductor apparatus of claim 13,
wherein the gate finger and the auxiliary electrode further include another metal stacked on respective nickel or the metal primarily containing nickel.
